(19) United States
(12) Patent Application Publication
(10) Pub. No.: US 2009/0087563 A1
(43) Pub. Date: Apr. 2, 2009

(54) COATING OF DISPLACER COMPONENTS (TOOTH COMPONENTS) FOR PROVIDING A DISPLACER UNIT WITH CHEMICAL RESISTANCE AND TRIBOLOGICAL PROTECTION AGAINST WEAR

(76) Inventors: Gerald Voegele, Sindelfingen (DE); Thomas Weisener, Ditzingen (DE)

Correspondence Address: DUANE MORRIS LLP - Philadelphia;IP DEPARTMENT, 30 SOUTH 17TH STREET, PHILADELPHIA, PA, 19103-4196, US

(21) Appl. No.: 11/718,370

(22) PCT Filed: Nov. 2, 2004
(86) PCT No.: PCT/DE05/01960

§ 371 Date: May 1, 2007

(30) Foreign Application Priority Data
Nov. 2, 2004 (DE) 10 2004 052 866.7

(51) Int. Cl. C23C 16/44; F16H 55/17; F16H 55/00

(52) U.S. Cl. 427/255.28; 74/434; 74/462

(57) ABSTRACT

The invention relates to a method for producing a displacer component that is coated with a diamond coating or layer as well as such a structural component (as a tribologically loaded part). In order to convey or dose a chemically aggressive fluid, a basic structural component (2, 3) is accurately produced in a first dimension (m1) from a chemically not sufficiently resistant but mechanically sufficiently stable first material (A) in a material removing manner. At least the surface sections of said first accurately sized basic component (2, 3) which are actively involved in the displacement are then coated with an at least 1 μm thick layer (10) of synthetic diamond in a coating process such that a second size (m2) of the structural component is obtained that fits the displacer unit (1). The inventive method makes it possible to produce a chemically resistant, friction reduced structural component for displacing the chemically aggressive fluid.

The invention in a general sense relates to a method for producing a displacer component that is coated with a diamond coating or -layer, as well as such a structural component (as a tribologically loaded part) for a fluidic displacer unit like a pump or dosage unit, wherein units with rotating and axial operation are comprised (piston displacer, screw displacer, or rotation displacer), preferably into the component with rotating operation.

The invention also relates to a hard metal gear coated with synthetic diamonds for a fluidic mini- to micro-unit. An associated CVD method for manufacture is also concerned.

State of the art gears are typically made from metals. These may be not resistant or not sufficiently resistant for their task in the context with chemically aggressive media, in particular in the acidic ph range. According to the state of the art a complete gear can be manufactured from a chemically inert material. The manufacturing methods employable therefore however are very expensive, e.g. coordinate grinding, when high precision is required.

From DE-A 101 46 793 hard bearing materials shaped as bearing bodies are known, which can be aligned correctly through positioning in softer carrier material. The support is to be improved for mini- or micro pumps according to the proposals contained therein. DE-A 37 28 946 shows an assembly for homogenizing through a homogenization slot, which is confined by polycrystalline diamond sinter layers according to the suggestions therein, refer therein in particular to claim 1 and column 3, lines 31 to 45 and column 4, lines 35 to 43. From WO-A 97/07264 a carbide substrate is known, which is coated with polycrystalline diamond, wherein an artificial diamond in the sense of a synthetic diamond is described with respect to two manufacturing processes, re. therein page 1, middle paragraph PCD, and via a CVD, where the latter one deposits a diamond film. By nature PCD inserts for tools shall be provided according to the suggestions therein, wherein tungsten carbide is being used, re. therein page 3, first paragraph, in connection with a CVD-layer film made from diamond.

The technical object is to obtain a chemical resistance or an improvement of the wearing protection at the designated structural components.

Through a coating of a basic structural component, which is preferably several microns thick, and thereby homogenous and chemically tight, preferably with polycrystalline diamond, a chemical inertness of the component is provided (claim 1). The inertness is based on the high resistance of the synthetic diamond layer relative to fluidic substances with which it is in contact (claim 3, claim 4). The synthetic diamond layer is polycrystalline in a physical sense, and differs from the monocrystalline natural diamonds, which have an almost perfect monocrystalline shape. The polycrystal is a crystalline solid body (here also in the sense of the deposited layer on the surface of the substrate as a basic structural component from the first material), whose crystalline structure is irregular. It is comprised of many small single crystals, so called crystallites, which are separated from each other through grain boundaries. Most crystalline solid bodies in nature are polycrystalline, differing from the monocrystalline natural diamonds. Regarding its crystal size the non-monocrystalline (polycrystalline) diamond layer is preferably provided with crystal sizes so small, that they can be coated onto the surface of the first material of the basic structural component in several layers. The several layers of these crystal layers are called a nanocrystalline layer. The term is understood in a physical sense such that it serves as a definition in contrast to polycrystalline diamond layers which are created through sintering.

The properties of a nanocrystalline diamond layer (claim 27) are favorable with respect to the creation of cracks under mechanical loads. The propagation of a crack mostly occurs in circumferential direction and does not extend or hardly extends in radial direction, so that dangerous openings, through which cracks are created, do not occur in radial direction here, and the chemical tightness of the surface cannot be endangered. That direction is understood as a radial direction which extends perpendicular to the extension of the surface, and that direction is defined as circumferential direction which extends parallel to the surface.

If a CVD coating process is used as coating process, a preferred polycrystalline diamond layer is created, which is nanocrystalline in the sense of the previously described meaning. It has several layers of crystal planes, which are located above the substrate. This sets them apart from monocrystalline materials, here shaped as layers. The CVD coating method is thus particularly favorable (claim 2, 29).

The coating with the preferably physically polycrystalline diamond layer smoothes rough surfaces of the underlying material. Rotating components are preferably coated in this manner.

According to the process a gear, as an example of a rotating component (claim 24), can be “made to dimension” from a chemically not inert material and can obtain the inert property with a coating with synthetic diamonds subsequent to this manufacturing process, forming a second dimension (claim 21, 24, 25).

The two mentioned dimensions, “first dimension” and “second dimension”, represent the initially performed recessing at the basic structural component, which is performed on an interior component radially to the inside and on an exterior component radially to the outside, in order to precisely obtain the first dimension. After this recessing of the basic structural component the deposition of a synthetic diamond layer with at least 1 μm thickness is performed for obtaining the second dimension, which represents the reversal of the recessing and thus provides a larger radial dimension at the interior component and reduces the radial interior dimension of the formed coated surface on the exterior component. The second dimension thus obtained determines the precision of the function of composite components in the displacer unit to be formed.

Since the first dimension is not sufficient for such a function the coated shape of the two “complimentary” components (claim 16) is sufficient for the function and satisfactory (claim 28). The two components are complimentary in the sense that they functionally belong together.

The “dimensions” thus each represent a plurality of dimensions, also in axial direction, in case of front faces (axial support surfaces) re. claim 17.

The manufacturing process is suited in particular for micro gears (claim 7, claim 8), but can also be used for larger gears. Hard metal as a first material of the basic structural component can be machined very precisely and the diamond layer can also be deposited with the most precise tolerances, so that inert gears with highest precision can be produced. In the pump as an example of a rotating displacer all bearing components are coated in such a way that at least each surface which bears against another surface (relative motion) is coated (claims 13, 14, and 17). This also relates to the effective feeding surfaces of the displacer and also to the front faces.

A chemical inertness of the components which are pre-shaped from the chemically non resistant material can be accomplished all around, in particular completely, when all surfaces are coated with the synthetic diamond layer in order to avoid a corrosive aggression of fluidic media (claim 13, claim 14).

It is to be noted that three dimensional bodies can be coated with the CVD coating process (claims 2, 29). In such a three dimensional structure a differentiation is to be made between contact surfaces which are not functional for feed operation, feeding surfaces within a displacer and possibly such surfaces, which are neither functional for feed operation or contact surfaces in the sense of bearing surfaces. All these surfaces can be provided three dimensionally in space, thus do not have to be flat/planar, in order to be able to be coated with the synthetic diamond layer via the CVD process.

In case of a feeding of the above said fluidic media also such media are allowed, which contain abrasive particles. This fluid can additionally be chemically aggressive, but it is also mechanically aggressive due to the particle content fed by it. Chemical resistance as such describes the displaced medium, the improvement of the wearing protection also describes the mentioned abrasive particles, which are subject to displacement within a fluidic medium.

Compared to a ceramic component a hard metal component coated with synthetic diamond has the advantage of being superior with respect to chemical resistance.

With this process small and very exact shapes can be manufactured from hard metal, for which the manufacturing cost compared to an (inert) ceramic component of comparable precision is lower (claim 10, claim 11). Here it is implied that a ceramic or plastic component would be required in the pump for functional reasons, so that in effect there is no possibility of choosing this material.

With plastic as a base material the contours would have to be previously corrected accordingly due to often occurring swellings. The gaps thereby induced lead to higher hydraulic losses.

Compared to the plastic component the claimed structural component (claim 30, claim 31) has the advantage that a substantially higher service time is reached due to the minimum wear and swelling does not occur. At the same time an application in functionally demanding areas like dosage technology, high pressure feeding is possible through the precision that can be reached by diamond coated hard metal structural components.

A high quality of the coating is accomplished through the CVD coating process (CVD=chemical vapor deposition) which is performed at higher temperatures (claim 2, claim 9, claim 29). A nanocrystalline diamond layer is obtained by it. Relative to a PVD coating process (PVD=physical vapor deposition) a significantly improved binding of the diamond layer to the hard metal substrate is accomplished.

The particular properties of the gear manufactured according to the claimed process (claim 30) target in particular the application in pumps (claim 19) of any kind. The manufacturing process of the gears may be complex, but the technical requirements e.g. in chemical production compensate for the effort and for the costs involved due to the lack of alternatives.

The gears are the functional components of a gear ring- or gerotor pump or of a -motor (claims 5, 6, and 18)

Such gears can be applied in particular in rotating displacement pumps like outer gear pumps or inner gear pumps (e.g. gear ring pumps). The gears are e.g. an internally geared outer gear and an externally geared inner gear. The gearing is preferably cycloid (claim 18). Two outer wheels are also possible (claim 34).

The method is also suitable for externally geared gears (claim 23) of a displacement pump.

Through this special suitability for externally geared gears or gear ring pumps in smallest formats, the claimed process can be extended to all displacement components, which are not only pure rotation displacers, but which also have axial movements as displacers or screw displacers (claim 19). If the thickness of the synthetic diamond layer is increased to values larger than 5 μm, or in particular larger than 10 μm, the chemical resistance is increased (claim 20). However, already with a small thickness of the diamond layer a friction and wear reducing effect can be felt and becomes effective.

Herein a friction reduced embodiment of the displacement unit is emphasized, wherein all surfaces in tribological contact are covered (coated) with the synthetic diamond layer. All friction surfaces created are thus matched functionally and in dimensions so that friction is reduced. The associated components (according to claim 31) are the ones which work together functionally in order to form the displacer unit. Here it is understood that the tribologically loaded (bearing against each other) surfaces are not only radially oriented surfaces, but can also be face surfaces, where an axial support of the moving component occurs.

The adhesion of the diamond layer on the surface of the basic structural component made from the first material, preferably hard metal, is improved by a matrix formed at least on the surface of this hard metal (claims 12, 15). Here a cobalt binder having between 6% and 15% cobalt content is being used. A binder matrix (claim 15) is created which reliably connects the diamond layer with the base material. This connection also serves the cohesion of the crystals of the hard metal, e.g. tungsten carbide. The binder matrix keeps these crystals together, preferably at the surface, but also via the entire radial extension of the base material, which is e.g. sintered from a powder mix of cobalt powder and tungsten carbide powder. Preferred weight percentages are below 15% of cobalt binder (claim 12, claim 15).

If cobalt is selected as binder material for the hard metal special cobalt binder is not necessary anymore at the surface of the hard metal.

For the duration of the coating process the component is supported (held in bearings, or it rests in a support). This support can have any shape. This support engages with a section into a specifically formed section of the structural component, e.g. a flat surface for a standing support or a recess for a hanging support. As a support feet or wires or otherwise shaped carriers are suitable. At least two flat surfaces are preferred (claim 32) in order to be able to support the component to be coated on two different surfaces and to coat the respective surface at the other support, which was not coated during a support, at least once.

However, a gear which is supported during coating can also be designed at the foot of the tooth in such a way that a touching during the operation or mutual engagement does not occur due to separation. A gear can also be supported in an intermediary manner at these locations. An additional support possibility would be through two wires or two line contacting elements as e.g. knife edges.

The invention is subsequently described and thus explained and supplemented with reference to several embodiments.

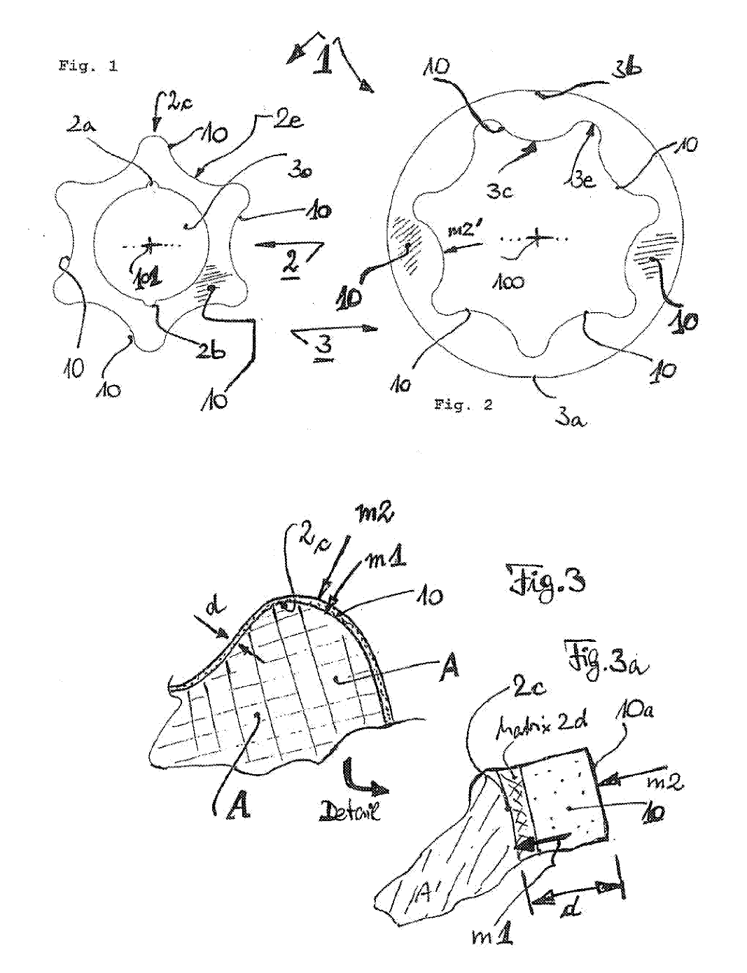

FIG. 1 is a diamond coated outer gear 2 (as interior rotor) for a gear ring pump.

FIG. 2 is a diamond coated inner gear 3 (as outer rotor) for a gear ring pump.

FIG. 3 is a sectional view of a surface of the outer gear 2.

FIG. 3a is a detail of FIG. 3.

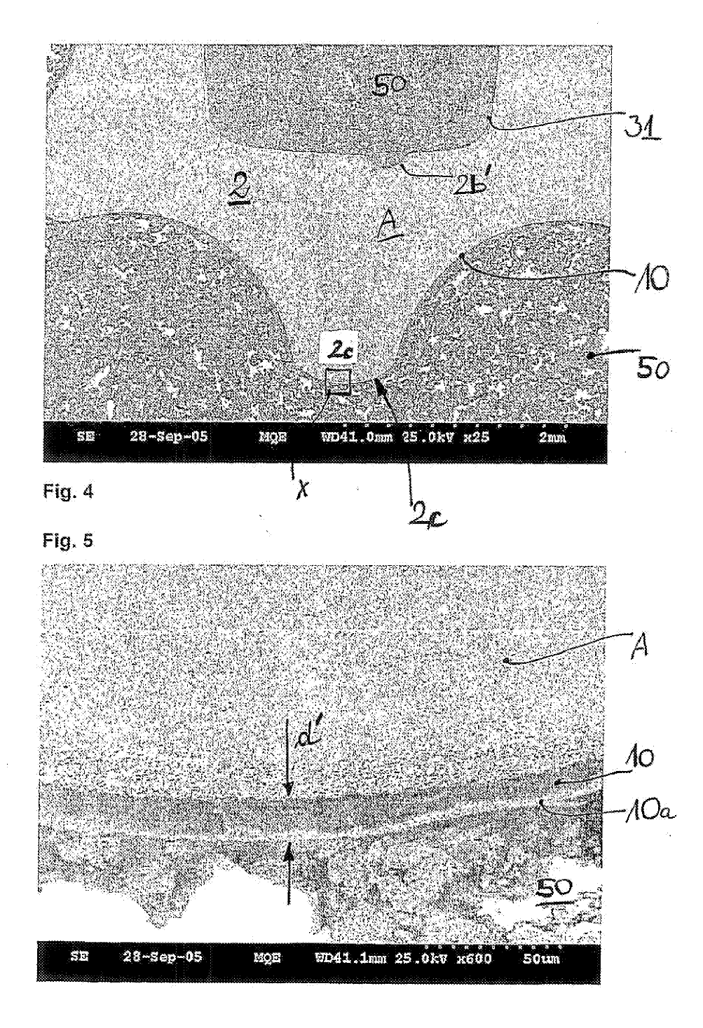

FIG. 4 is a ground section of a gear coated with a synthetic diamond layer 10 as inner rotor (light gray material in the ground section, designated with A), surrounded with a bedding compound 50. The section is perpendicular to the axis of the interior rotor. The lower tooth 10 is shown in an enlargement in the subsequent picture.

FIG. 5 shows an enlarged detail X of the previous figure, at the tooth 10 in the encapsulated area and above the diamond layer 10 (solid black) the hard metal material A is located and below the bedding compound from a mixture of epoxy resin and copper is located.

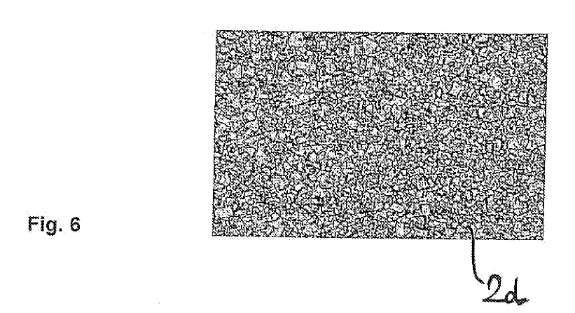

FIG. 6 is a structure of a 2d binder matrix from hard metal (tungsten carbide) and cobalt in a surface structure which is enlarged 1,500 fold. This has been created through cutting and a grinding through the material A in the course of a metallurgic surface analysis.

The gears 2, 3 according to FIG. 1 and FIG. 2 are the functional components of a fluidic gear ring- or gerotor pump or such a fluidic motor 1 of such kind with two radially displaced axes 100 and 101. The gears are an internally geared outer gear 3 and an externally geared inner gear 2 with a shaft opening 30. The gearing is cycloid.

In a fluidic pump (or fluidic motor) 1, which is not shown separately with a housing, which is not shown, the pump has bearings on both sides or on one side of the moving first rotor 2 with the second rotor moving along.

In the pump all bearing components are coated with a diamond layer 10, as shown in an enlarged scale in FIG. 3, so that each surface section, which moves relative to another surface section in assembled state (relative motion) is coated. Here two rotors in disassembled state are shown in FIGS. 1 and 2.

The basic shapes which are initially generated through machining (or which are created from molded shapes) are shown in FIGS. 1 and 2, here already shown with coatings 10 indicated, which are to be deposited and which are shown in detail in the enlarged views of FIG. 3 at a location 2c of an outward protruding tooth of an inner gear 2. This FIG. 3 can be inverted (complimentary) and also be transposed into FIG. 2. If the basic shape has to be manufactured initially, it does not have the diamond coating 10 yet, which is only deposited during the further course of the process.

A basic shape is molded and fabricated through machining. The plurality of dimensions generated herein is represented in FIG. 3 by the two dimensions m1 and m2 in a symbolic manner. In particular in the enlarged detail of the diamond layer 10, which is shown here with its surface 10a, the basic shape is shown with its first dimension m1, which is recessed relative to a mechanically better fitting dimension with reference to the complimentary structural component, which is shown here in FIG. 2 as an internally geared outer gear. The initial shape can refer to an initially still imprecise dimensioning, it is machined to the first dimension m1. This first dimension is coated with a diamond layer 10 in the coating process to be described, possibly with a matrix binder 2d located below, at least on the surface 2c. With the diamond layer the second symbolic dimension m2 is reached, which cooperates dimensionally exact with the inward facing surface of the outer gear, which is actively involved in the feed operation and which has been manufactured in the same manner.

A basic gear contour is preferably wire eroded during the manufacture of the basic shape, this means with a particular suitability for the manufacture of micro gears with or without high shape precision. Other manufacturing processes for manufacturing hard materials like grinding or laser cutting are also possible.

The height and planarity of the gears (as a basic component) is reached through grinding (and tapping) in the micron range. Hard metal gears made from the material A are being recessed in an equidistant manner on their functional feed surface section 2e, 3e for the subsequent coating, thus machined with a respectively smaller (or larger) dimension. A respective tooth 2c, 3c protrudes further (towards the outside or the inside). The same applies for front faces, which are shown here in top view in FIGS. 1 in and 2 with a diamond layer 10 already deposited. Also the front face located on the opposite side is machined accordingly in order to obtain the first dimension m1, still without the diamond coating 10. In the same manner the shaft surface of the pass through 30 can be created through respective machining for obtaining precision of the dimension m1. Also the outer surface of the outer gear of FIG. 1 can be manufactured accordingly precisely to the dimension m1.

The dimension m1 here represents the respective applicable dimension at the respective surface section, thus the outer gearing, the interior diameter, the front faces, the inner gearing of the outer gear, the front faces and the outer surfaces of the outer gear, which can be rotatable in housing. A pretreatment of the said surface sections can follow for improving the adhesion of the diamond layer 10 to be deposited.

Preferably through a CVD process the “polycrystalline” (not monocrystalline) chemically tight diamond layer 10 is deposited onto gear 2 or/and 3, which provides a chemical resistance, in particular when functioning as a pump gear. Tribological properties can also be improved, this means friction is reduced.

The substrate material A is hard metal. A preferred embodiment is hard metal having less than 15%, in particular in the range of 6% cobalt binder as matrix 2d at least on the feeding surface sections 2c, 3c, which are tribologically loaded. This structure can also extend into the entire material A. In the same manner the front faces are provided with the matrix, which is not shown separately. Also radial cylindrical or annular surfaces on the inside and on the outside an be coated accordingly, which is not shown in detail either.

Through the coating 10 in the detail view of FIG. 3a an entire thickness “d” of the layer is reached, which includes the matrix layer 2d and the synthetic diamond layer 10. Thus the second dimension m2 is defined, which defines the outer dimension depositing onto the first dimension m1 which is selected in the embodiment for the inner gear. This second precision dimension m2 symbolizes the precise functional dimensions, which are necessary to operate with a respective radial interior dimension of the outer gear according to FIG. 2 in a feed effective manner.

The above explanations also apply accordingly for the radial interior dimension of the outer gear and to a matrix 2d at least present on the surface with a diamond layer 10 for obtaining the precise interior dimension thereupon, also symbolically designated with the reference m2. Also here the binder matrix can extend entirely into the material A.

The optimum thickness “d” of the layer is in the range of 10 μm to 15 μm, with or without the surface matrix layer.

The matrix 2d, which includes cobalt binder at below 15% by weight, in particular in the range of 6% by weight, becomes a component of the substrate or the substrate material A. It symbolizes the basic component onto which the synthetic diamond layer 10 is deposited preferably through a CVD process. The binder matrix 2d, which is at least provided on the surface of the material A, but which can also comprise the entire material, describes a material “hard metal”, in which the tungsten carbide (WC) crystals are held together by the matrix. It thereby forms a connecting part or some kind of “adhesive”, which keeps the hard metal crystals together. In FIG. 6 this structure can be seen in an exemplary manner, which resulted from the manufacturing process in which a powder of WC is mixed with cobalt powder with the said weight percentages, and then sintered. A sectional view of the material A is shown with a magnification of 1500.

For the coating process not shown supports for setting up each part are provided, so that the “functional surfaces” can be coated in a homogenous manner and the thinner coating on the support surfaces does not impair the overall function. These are positioned in sections of the gear where there is no tribological load during operation. In order for each of the support surfaces to be able to be coated at all, at least two positioning surfaces or support surfaces have to be provided for each structural component.

The coating process 10 is interrupted in order to allow repositioning.

The support locations are in those spots of the pump component in which there are no high tribological loads during the operation of the pump.

On the outer gear 3 at least two opposite flat surfaces 3a, 3b are located in which the gear 3, geared on the radial inside can stand on a flat surface. The flats do not negatively affect the subsequent support of the outer gear at the outer diameter in a detrimental manner.

In the inner rotor 2 at least two cutouts 2a, 2b are provided in the shaft bore in which the gear which is geared on the radial outside can be held on a wire in a hanging manner. The cutouts can be rounded or have edges.

On a gear alternative support locations can be created in areas in which no tribological loads occur, or in which no relative motion between two functional components occurs. Such surfaces can be created through free cutting, refer to the example of the flat.

In an involute geared gear the support locations can be in the root circle of the inner or outer gear, where no relative motion takes place.

The coating 10 with synthetic diamond leads to a chemical inertness of the surface after a certain height (thickness) of the layer. The thickness of the layer, considering the tolerance requirements, should be above 1 μm and below 40 μm, preferably substantially 15 μm. The thickness of the layer is selected depending on the coating process, so that a chemically tight layer is created. Simultaneously wear has to be taken into consideration which depends on service duration and which is load specific and which is normally minimal. This has to be verified through testing and has to be incorporated into the height of the initial layer (height or thickness) to be defined.

It should be noted that the incorporated layer of synthetic diamond provides broad ph-resistance relative t both acids and bases. The use of diamond coated gears in acidic media competes e.g. with gears which are made from ceramics or plastics. Ceramic materials have excellent resistance to acids, but they are sensitive relative to bases. This applies in particular to common oxide ceramics.

With metals it is the other way around, they are not attacked by alkaline media, but only have little resistance against acids depending on the basic and finishing elements.

The diamond layer 10 with a coefficient of friction in the range of 0.1 significantly reduces the friction between the moving parts. When displacer components are being moved relative to each other, in particular when gears roll on each other or relative to each other, a comparatively small energy transfer into the moving surface occurs. The related low thermal load of the microstructure is a determining factor for the wear reduction. Metals and also ceramics have significantly higher coefficients of friction in the range of 0.2 to 0.4, but often even higher.

For the optimum design of the friction ratios with respect to minimal wear it is useful to coat all surfaces which have relative motion (rotating, rolling) with a layer of synthetic diamond, since the wear rate in the tribological surface contact is minimal. In the area of pumps an exception can be e.g. the shaft in the area of the shaft seal.

In the area of pumps this requirement means that all further functional components, as e.g. the radial and axial support elements and the shafts, should be manufactured according to the same process and provided with a diamond layer 10, as shown in FIG. 3 for an outer gear tooth.

A non monocrystalline diamond layer can only be deposited on a limited number of substrates as a base material (material of the component to be coated) with sufficient thickness. Besides ceramic, also hard metal is among them. Within hard metal different binder systems are being differentiated, in which cobalt o r nickel form the matrix substrate. For diamond coating 10 in particular hard metal A with cobalt binder 2d is suitable. This keeps the hard metal crystals together. A ground section of such a material is shown in FIG. 6 with 1,500 fold magnification.

For an optimum connection of the layer 10 to the substrate the binder matrix 2d which is at least provided on the surface does not include too much metal, to which the diamond layer does not adhere in an optimum manner. At the same time there cannot be too little binder metal, since the substrate otherwise becomes brittle and the carbides located at the surface are not being held sufficiently. A preferred binder percentage is below 15%, in particular at approximately 6% cobalt (variance of ±20%). Such hard metal is used for tools today, where the so called PKD coating (PKD is a polycrystalline diamond) is being used for the highest requirements with respect to lifecycle extension.

A pretreatment of the substrate is a factor influencing the quality of the layer adhesion. It comprises among others cleaning and etching processes for preparing the surface. In the future also hard metals with other binder- or substrate percentages at least on the surface can be used.

The layer deposition 10 is performed with ±10% precision today. However, it is well controllable, since the layer growth occurs slowly. In order to reach a variation of the height of the layer at spaced locations that is as small as possible it should be limited to the bare necessities from a chemical point of view.

The coating of the synthetic diamond layer 10 is performed in an equidistant manner that means a spike turns into a rounded contour on the surface 10a. This means that for reaching the functional contour after the coating process a shape must be manufactured previously, which is corrected (reduced) for by the amount of the layer. This is represented in a symbolic manner by the two dimensions m1, m2.

Real embodiments of such coatings 10 shall be described with reference to FIGS. 4 and 5. FIG. 4 is a grond section perpendicular to the axis of an outer gear operating as an inner rotor 2, as it is shown in front view in FIG. 1. The outward protruding tooth 2c is recognizable in the lower, middle area of the figure, surrounded by a bedding compound 50 which is a conductive mixture made from epoxy resin and copper. A shaft opening 31 is also recognizable, filled here with the same bedding compound but open in normal state of the component. In comparison to FIG. 1 the shaft opening 31 is provided as a polygon, but it has the support location 2b′ located on the bottom, comparable with the support location 2b of FIG. 1.

The microstructure of material A, which appears light gray and homogenous, is coated on the surface with a synthetic diamond layer 10, which can be recognized from the schematic depiction of FIG. 3, but can be described in more detail in its real structure with reference to FIG. 5. Here the base material A, which is hard metal, can be seen in light color in the upper portion of the depiction. The diamond layer 10 deposited thereupon with a CVD process has a thickness d′ as previously described with reference to FIG. 3. This applies to the case where the matrix layer 2d extends to the whoe of the material A below the synthetic diamond layer.

The surface 10a of the synthetic diamond layer 10 with a nanocrystalline microstructure is the surface which comes in contact with the opposite surface of the complimentary component during operation, like e.g. of the outer rotor 3 according to FIG. 2, whose inward facing surface is a diamond layer 10 whose surface 10a is in tribological contact with the surface shown in FIG. 5.

The depiction of FIG. 5 is an enlarged detail of the area X from FIG. 4, wherein FIG. 4 is a 25 fold enlargement of the original component, and FIG. 5 is a 600 fold enlargement of the original component, so that the enlargement factor between FIGS. 4 and 5 is the factor 24.

The grains or crystals shown in FIG. 5 below (closer to the black bar) the surface 10a of the synthetic diamond layer 10 constitute a bedding compound, into which the rotor was bedded, before being processed for a ground section. This bedding compound 50 does not form a component of the complete rotor component for which each possible combination of outer gear, inner gear, and outer gear/outer gear is possible.

The manufacture of gears, micro gears in particular, or highly precise tolerance gears from hard metal is possible through precision manufacturing processes, as e.g. wire eroding, grinding, laser cutting, lapping, honing, etc. in a cost effective manner. These remove material.

Wire eroding in particular has advantages when manufacturing the contours of highly precise micro gears. This applies to the basic manufacturability of gears with state of the art processes.

Gears with internal teething cannot be manufactured through profile grinding with an outer diameter of less than 15 mm. The manufacture through coordinate grinding is very complex. Thus micro gears can currently only be manufactured through a molding process like e.g. injection molding. Thereby only limited precisions of gears can be accomplished, which are inferior to the ones which are required for high performance hydraulic properties of a pump, e.g. for creating high pressures or providing a precise dosage.

For gears with external teething the above applies with limitations, since smaller outer diameters can be manufactured. But also in this case the manufacture of precise contours is complex.

Compared to manufacturing highly precise micro gears through grinding, wire eroding technology is a cost effective alternative.

By combining diamond coating and hard metal gears, a distinct advantage compared to ceramic gears can be accomplished. In specific situations the process basically expands the manufacturability of inert highly precise micro gears.

The manufacturing specifications can also be used for all functional components besides gears, which are in tribological contact. These also include bearings and shafts.

1. A process for producing at least one structural component for a fluidic displacer unit for displacing a chemically aggressive fluid;
wherein at least one basic structural component is accurately produced in a first dimension from an insufficiently chemically resistant, but sufficiently mechanical stable, first material in a material removing manner;
wherein the structural component, accurately dimensioned with reference to the first dimension, at least on the surface sections which are actively involved in the displacement, is coated with synthetic diamond through a coating process so as to produce a diamond layer at least 1 μm thick, such that a second dimension of the structural component is obtained that fits the displacer unity;
producing a chemically resistant friction reduced structural component for displacing the chemically aggressive fluid.

2. A process according to claim 1, wherein the coating process is a CVD diamond coating process.

3. A process according to claim 1, wherein the preferably polycrystalline diamond layer is thinner than 40 μm.

4. A process according to claim 3, wherein the diamond layer is provided in a thickness of about 10 μm to 15 μm.

5. A process according to claim 1, wherein the structural component is at least a gear of an internally teethed displacement pump.

6. A process according to claim 5, wherein two structural components are produced as an outer gear and an inner gear for a tooth ring displacement pump.

7. A process according to claim 1, wherein the structural component is a mini-unit and has a diameter of less than 10 cm.

8. A process according to claim 1, wherein the structural component is a micro unit and has a diameter below 15 mm.

9. A process according to claim 1, wherein the coating process operates above 800° C.

10. A process according to claim 1, wherein the first material is not a ceramic material.

11. A process according to claim 1, wherein the first material is a hard metal.

12. A process according to claim 1, wherein less than 15% of a cobalt binder is disposed at least on the surfaces of the structural component which are to be coated with the diamond layer.

13. A process according to claim 1, wherein the diamond layer is disposed on all surface areas of the structural component.

14. A process according to claim 1, wherein two structural components are manufactured and all opposed surface sections are mated with the diamond layer.

15. A process according to claim 1, wherein a binder matrix is formed in a pretreatment at least on the surface sections which are to be coated with the diamond layer.

16. A process according to claim 1, wherein a first and a second structural component are manufactured, essentially having a complimentary outer and inner shape, respectively.

17. A process according to claim 1, in which process all surface sections of the displacer unit that are moving relative to each other are coated with the diamond layer.

18. A process according to claim 6, wherein the teething of an outer gear and an inner gear is cycloid or involute.

19. A process according to claim 1, wherein the structural component is a component of a screw pump, piston pump, or rotating displacement pump.

20. A process according to claim 1, wherein the diamond layer is at least 5 μm thick.

21. A process according to claim 17, wherein all surface sections to be mated and bearing against each other are recessed to a first dimension in an equidistant manner, and the diamond layer is deposited onto a recessed surface for forming the second dimension, with which the respective coated structural component of the displacer unit operates.

22. A process according to claim 1, wherein the structural component has at least a support geometry on which the structural component is supported during the coating process.

23. A process according to claim 1, wherein two structural components are manufactured as two outer gears of a displacement pump.

24. A process according to claim 1, wherein the at least one structural component is a component that rotates during operation.

25. A process according to claim 1, wherein the diamond layer is polycrystalline.

26. A process according to claim 1, wherein the diamond layer is not a sintered layer.

27. A process according to claim 1, wherein the diamond layer is a nanocrystalline layer, such that multiple layers are formed as a synthetic diamond layer on the surface of the first material.

28. A process for manufacturing associated structural components of a fluidic displacer unit;
wherein at least two structural components are manufactured from a mechanically sufficiently stable first material;
wherein the structural components are coated with one layer of a synthetic diamond with a coating process on the surface sections actively involved in displacement and their face sides;
so as to form a friction reduced displacer unit for displacing the fluid.

29. A process according to claim 28, wherein the synthetic diamond is deposited with a chemical vapor deposition (CVD) process.

30. A gear component of a displacer unit, manufactured or manufacturable as an inner or outer component of a dosage or feed pump according to the process of claim 1.

31. The gear component according to claim 30, further comprising a second gear component that is complimentary to the gear component.

32. The gear component according to claim 30, further comprising a support geometry to support the gear component during the coating process.

33. The gear component according to claim 30, wherein the gearing is involute or cycloid.

34. A process according to claim 1, wherein the gearing of a first outer gear and another outer gear is cycloid or involute.
